(19) United States
(12) Patent Application Publication
(10) Pub. No.: US 2009/0066316 A1
(43) Pub. Date: Mar. 12, 2009

(54) Electrokinetic Method for Determining the Electrostatic Charge State of a Porous Membrane During Filtering and the Use Thereof

(75) Inventors: Herve Suty, Champigny Sur Marne (FR); Helene Habarou, Rueil Malmaison (FR); Maxime Pontie, Angers (FR)

Correspondence Address: COATS & BENNETT, PLLC, 1400 Crescent Green, Suite 300, Cary, NC, 27518, US

(73) Assignee: OTV SA, Saint-Maurice (FR)

(21) Appl. No.: 11/720,406

(22) PCT Filed: Nov. 28, 2005
(86) PCT No.: PCT/FR05/02950

§ 371 Date: Dec. 7, 2007

(30) Foreign Application Priority Data
Nov. 29, 2004 (FR) 01412632

(51) Int. Cl. G01R 19/00

(52) U.S. Cl. 324/72

(57) ABSTRACT

The invention relates to an electrokinetic method for determining the electrostatic charge state of a porous membrane during filtering by measuring trans-membrane variations of a flow potential. The use of the inventive method for controlling and characterising the filtering membrane cleaning efficiency is also disclosed.

The invention concerns an electrokinetic method for determination of the electrostatic charge state of a porous membrane during filtering, by measurement of its flow potential.

This analytical method is particularly useful for the optimization of the use of microfiltration (MF), ultrafiltration (UF) and nanofiltration (NF) membranes.

The invention concerns the utilization of this tool for verifying the charge state of the membrane before it is put into service for the production of water, for determining the state of clogging of said membrane, for determining the frequency of its cleaning, and monitoring and characterizing the efficacy of cleaning. In particular, the method according to the invention verifies the charge state in the pores of said filtration membrane.

The method according to the invention advantageously associates measurements of flow potential during filtering (MF, UF or NF) with more conventional measurements of hydraulic permeability.

The purification of mains water by the utilization of membranes is widely used on the industrial scale. Separation is assured by a pressure gradient that is the essential driving force.

The method according to the invention is based on the following principle: when a liquid is constrained by the effect of a hydrostatic pressure to pass through a porous medium, the charges of the mobile portion of the double layer that develops on the walls of the pores migrate toward the outlet of the pores. If the walls are negatively charged, the mobile charge consists of positive ions and a flux of positive charges appears in the direction of the hydrodynamic flux whereas an accumulation of negative counter-ions occurs upstream. The situation is similar if the walls are positively charged, in this case with a mobile charge consisting of negative ions and an accumulation of positive counter-ions. This charge imbalance causes the appearance of a potential difference measured between the two ends of the pore. The steady state is attained when the flux of charges due to the pressure is balanced by the flux of charges induced by the potential difference. The potential difference is then called the flow potential. This magnitude is measured at different pressures, preferably using a millivoltmeter with a very high input impedance in order not to disturb the established steady state.

The separation power of a porous membrane vis á vis a mixture of charged solutes (ions, molecules) results simultaneously from discrimination as a function of the size, the charge and the conformation of the species to be retained; the effects of electrical charges stemming from the physical-chemical nature of the membrane material can play an important part in the phenomenon of clogging and the flow potential measurements evaluate them.

The filtration domains are generally defined in the following manner: “microfiltration” refers to a pore diameter equal to or greater than approximately 100 nm; “ultrafiltration” refers to a pore diameter from approximately 2 nm to approximately 100 nm, and “nanofiltration” refers to a pore diameter from approximately 0.5 nm to approximately 2 nm.

The membranes usually employed acquire a surface charge when they are brought into contact with water and the charge can vary significantly from one material to another. This charge is due either to the presence of ionizable functional groups intrinsic to the filtration material or, in the case of membranes having no ionizable groups, to the presence of residual ionic groups (carboxylates, phenolates) coming from steps of the process of fabrication of the membranes (Pontié et al., 1997; Shim et al., 2002). The charge may also be acquired by the adsorption of charged species present in the medium (for example ions, polyelectrolytes, ionic surfactants) that are deposited on the surface of the membrane material and contribute to the presence of a surface charge.

It is therefore indispensable to be able to determine accurately the surface charge state of a membrane, in particular the charge state of the pores, in order to facilitate the prevention of clogging liable to occur during filtration and that can, in certain cases, totally modify the initial characteristics of a membrane, considerably limiting its performance, but also optimize the frequency of cleaning of said membrane.

During the filtration process, the filtration membranes, especially hollow fiber filtration membranes, are subjected to a deconditioning phase, then alternating filtration cycles, and finally hydraulic washing (called “backwashing”) cycles and chemical cleaning cycles (using acidic and basic agents, for example). Initially, the deconditioning phase has the object of freeing the membranes of additives (surfactants, etc.) inherent to their fabrication in order to produce water of drinkable quality free of any contaminants. The “backwash” cycles are carried out using permeates resulting from the filtration, and the chemical cleaning cycles also using permeates but containing chemical products adapted as closely as possible to the nature of the clogging.

However, despite the use of these various steps, progressive clogging of the membranes occurs and the permeability decreases over time and, to restore the initial permeability, there must be periodically carried out a step of chemical cleaning using an acidic or basic agent, depending on the type of membrane, which necessitates shutting down the filtration device.

It is possible to follow the evolution of the permeability of a filtration material by measurements of hydraulic permeability. However, the hydraulic permeability serves essentially to validate the hydraulic cleanliness of the membrane, that is to say to evaluate if the backwashing and chemical cleaning steps are sufficient to restore the initial hydraulic permeability of the membrane. However, this measurement is not sufficiently sensitive to enable the state of chemical cleanliness of the membrane also to be evaluated. This is why simultaneously monitoring the charge state by measurement of flow potential enables the chemical cleanliness of the membrane to be obtained, that is to say verification that the chemical cleaning steps actually restore the initial charge state of the membrane.

A method for evaluation of clogging by local measurement of the zeta potential at the surface of a hollow fiber membrane has been described in US application 2003/024817. That process consists of a local measurement that does not give global information on the state of clogging of the pores of the membrane.

A system for evaluation of the modification of the surface charge of a membrane for extracorporeal circulation by a polyelectrolyte is described in the patent U.S. Pat. No. 6,454,998. In that system, which is not suitable for industrialization, a measurement of the flow potential of the polyelectrolyte is effected along the membrane and not across the latter.

The application JP11 107472 describes a measurement of the zeta potential at the surface of a membrane contaminated by surfactants; however, it is a question of a measurement effected along the membrane that gives no indication as to the charge state of the membrane and cannot be carried out on the industrial scale.

The technical problem to be solved therefore consists in providing a new method of measuring a value representative of the charge state of a porous membrane, in particular of the charge state of the pores of said membrane, that may be used during filtration.

The invention therefore concerns an electrokinetic method for determination of the electrostatic charge state of a porous filtration membrane during filtration, characterized in that the variations of the flow potential representative of the charge state of the membrane are measured during filtration.

The invention advantageously concerns an electrokinetic method for determination of the electrostatic charge state of a porous filtration membrane during filtration, characterized in that the transmembrane variations of the flow potential representative of the charge state of the membrane, in particular of the charge state of the pores of said membrane, are measured during filtration.

According to this method, the variations of the membrane potential difference between two electrodes is measured as a function of the transmembrane pressure, in such a manner as to follow the variations of the flow potential representative of the charge state of the membrane, in particular of the charge state of the pores of said membrane, during filtration, and the operations necessary for restoring the permeability capacities of said membrane are determined.

In contrast to existing methods in which the measurement is limited to the surface of the membrane (local measurement), the method according to the invention effects a measurement across the membrane (global measurement).

The method according to the invention therefore and advantageously evaluates the charge state in the pores and thus distinguishes any clogging of the surface from pore clogging. In effect, pore clogging leads to variations of the flow potential, whereas this is not the case with surface clogging. The method according to the invention therefore provides access to information relating to the charge state of the membrane at pore level, whereas the existing measurement methods have not provided access to this information.

According to a preferred aspect, the method according to the invention is implemented continuously.

In this case, the measurement can be effected directly with the solution to be filtered, without using a synthetic electrolyte solution.

The method according to the invention therefore determines the charge state of the pores of the membrane in the real fluid, directly in situ, continuously and on an industrial scale.

The invention also concerns the use of this method for validating the efficacy of the deconditioning step before putting membranes into service for the production of water, which ensures the elimination of the surfactants or other additives added for the conservation of the membranes. In effect, when the measurement of the flow potential as a function of time reaches a plateau during filtration, the membrane is deconditioned and can be put into service.

The method according to the invention also finds a beneficial use in monitoring and characterizing the efficacy of cleaning. In effect, if the membrane is cleaned correctly, its initial electrostatic charge is restored. These means for monitoring cleaning prevent irreversible clogging of the membrane that could progressively contribute to premature aging and to a loss of performance, and also limit the quantities of reagents to be used.

According to a preferred aspect, the method according to the invention may be implemented continuously and can advantageously highlight the presence of charged or uncharged clogging elements, determine optimally the necessity for, the frequency of and the nature of the cleaning and, accordingly, limit the quantity of water used. It can also verify that the membrane after cleaning has recovered its initial hydraulic permeability capacities.

This method can be used to complement measurements of hydraulic permeability.

The method according to the invention is applicable to pressurized filtration processes (non-immersed membranes) and to suction filtration processes (immersed membranes). It is particularly advantageous in the case of immersed membranes because the measurements of flow potential carried out are of very good stability because of the laminar flow regime in the suction filtration mode.

The method according to the invention may be used on any type of membrane, for example of polyethersulfone (PES) type, polysulfone (PS) type, cellulose acetate (CA) type, cellulose triacetate (CTA) type, polyvinyl difluoride (PVDF) type or other types and on any type of filtration module, for example plane, spiral, hollow fiber membrane, in frontal or tangential filtration mode.

The method according to the invention is advantageously not dependent on the area of the membrane to be analyzed.

Another aspect of the invention concerns a device for the determination of the electrostatic charge state of a porous membrane including an electrical circuit for the measurement of the flow potential, said electrical circuit including means for measuring said flow potential connected to means for reading said measurement.

Said measuring means preferably include two electrodes judiciously placed in the hydraulic circuit on respective opposite sides of the membrane. Ag/AgCl electrodes, where appropriate miniaturized and/or disposable, will be used with advantage.

Said reading means preferably include a millivoltmeter which advantageously has a high input impedance.

The invention is illustrated by the following nonlimiting examples.

### EXAMPLE 1

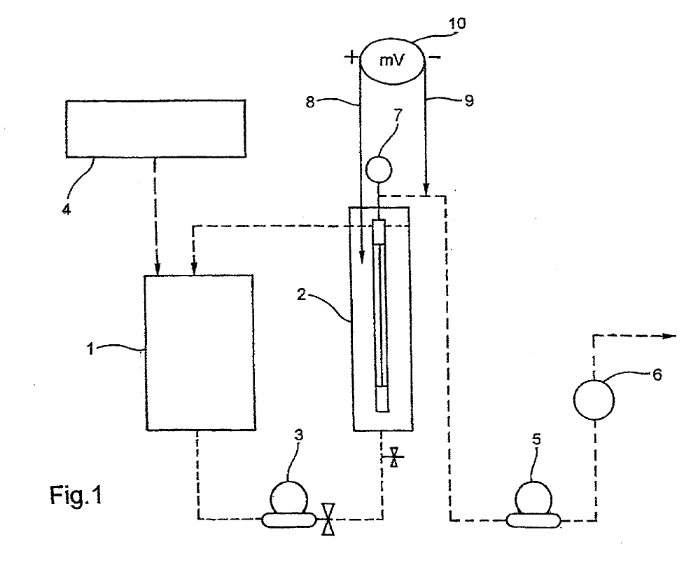

An immersed membrane pilot filter is represented diagrammatically in FIG. 1.

1/ Description of the Pilot Filter

The pilot filter used consists of a “feed circuit” and a “permeate circuit” as described hereinafter:

The “feed circuit” includes:
a double-wall stainless steel feed tank (1) with its temperature thermostatically controlled at 20° C. in which a temperature probe installed on the bottom of the tank and an agitation paddle are found,
a PVC column in which the filtration module (2) is installed,
a centrifugal pump (3) (HEIDOLPH KrP 25/4) for recirculation of the water between the tank and the column,
a raised upstream tank (4), for continuously feeding the stainless steel tank by gravity.

The “permeate circuit” includes a peristaltic pump with tube squeezer (5) (HEIDOLPH PD 5101), a (−1) to (+5) bar pressure sensor (KELLER PR21R) the signal from which is stored, and an electromagnetic flowmeter (ENDRESS HAUSER Proline promag 50) the signal from which is stored continuously.

Two manometers (6) and (7) measure the transmembrane pressure difference.

In the hydraulic circuit, Ag/AgCl electrodes (8) and (9) are associated with a millivoltmeter having a high input impedance (>10 Mohm) to enable measurement of potential differences (pd) that occur at the terminals of two electrodes each situated in one of the compartments on respective opposite sides of the membrane.

A 2×10⁻⁴M solution of KCl is used when deconditioning the membranes in order on the one hand to assure the deconditioning and on the other hand to maintain a minimum conductivity necessary for correct operation of the electromagnetic flowmeter.

2/ Experimental Protocol

The pilot filter is started at the beginning of the day and functions all day. It operates in dead-end filtration mode, at constant pressure with laminar flow (Reynolds number=1900). Samples are taken at the end of the day from the permeate and feed circuits. After taking these samples, the pilot filter is stopped momentarily; the entire system is then drained and then rinsed with dematerialized water.

The filtration module is then backwashed with ultrapure water (5 min at a pressure from 0.7 to 0.8 bar). The water collected during this backwashing was mixed to constitute an average sample. Hereinafter these average samples will be called backwash water (BW).

When a 40% loss of hydraulic permeability is reached, chemical cleaning is applied in accordance with the procedure indicated by the company producing the fibers. This step combines a first phase of cleaning with chlorine (200 ppm solution of free chlorine maintained at 20° C.) with a second phase of cleaning with citric acid (20 g/l solution maintained at 35° C.). Each of these two steps is applied as follows: (i) 15 min immersion with recirculation of the solution in the loop of the feed circuit; (ii) 30 min of filtration at 350 mbar; (iii) 5 min of immersion.

Between the two cleaning phases, the membrane module is immersed for a few minutes in a bath of ultrapure water.

3/ Results of Measurements

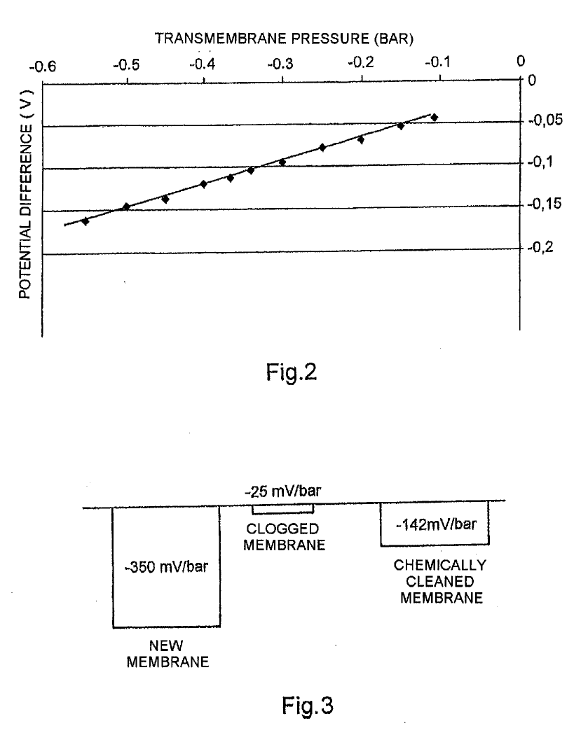

The measurements effected on a microfiltration (MF) membrane with 16 hollow polysulfone fibers with a mean pore diameter of 0.2 μm are plotted on the FIG. 2 curve.

That figure represents the evolution of the potential difference as a function of the applied transmembrane pressure difference (which here is negative because of the use of immersed fibers) for a solution of KCl at the concentration of 2×10⁻⁴M and a pH of 6.5.

The slope of the straight line observed is +350 mV/bar. To determine the value of the flow potential of this membrane, it is necessary to look at the connection of the electrodes; if the pd is the measurement of the difference between the feed compartment and the permeate compartment, in immersed mode (negative transmembrane pressure), the flow potential has the opposite sign to the sign of the slope. Here the flow potential is therefore −350 mV/bar and the membrane is thus charged negatively.

4/ Application: Demonstration of Irreversible Clogging

FIG. 3 represents the measurements of flow potential for an immersed polyvinyl difluoride microfiltration membrane when new, then when clogged by real effluent and finally after application of standard chemical cleaning (Cl₂ in a 1st step and citric acid in a 2nd step).

The measurement of the flow potential is effected for a solution of KCl at the concentration of 2.10⁻⁴M and a pH of 6.5.

The results show profound clogging of the membrane.

The method according to the invention can thus show that the chemical cleaning step is incomplete because it has not restored the initial charge state of the membrane.

1.-18. (canceled)

19. Electrokinetic method for determination of the electrostatic charge state of a porous filtration membrane,
characterized in that the transmembrane variations of the flow potential representative of the charge state of the pores of the membrane are measured during filtration by a measurement across the membrane of the membrane potential difference between two electrodes, as a function of the transmembrane pressure,
and wherein the measurement is executed continuously, directly in the solution to be filtered.

20. The method according to claim 19, wherein said membrane is an immersed membrane.

21. The method according to claim 19, wherein the filtration is effected under pressure.

22. The method according to claim 20, wherein the filtration is effected by suction.

23. The method according to claim 19 wherein the state of clogging in said membrane is determined by the measurement of the variations of the flow potential.

24. The method according to claim 19 wherein the state of clogging in the pores of said membrane is determined by the measurement of the variations of the flow potential.

25. The method according to claim 24, wherein the measurement is effected directly in the solution to be filtered without using a synthetic electrolyte solution.

26. The method according to claim 19 wherein the membrane is a microfiltration membrane.

27. The method according to claim 19 wherein the membrane is an ultrafiltration membrane.

28. The method according to claim 19 wherein the membrane is a nanofiltration membrane.

29. The method according to claim 19 wherein the method comprises the steps of measuring the variations of the membrane potential difference between two electrodes as a function of the transmembrane pressure, in such a manner as to monitor the variations of the flow potential representative of the charge state of the pores of the membrane during filtration, and of determining the operations necessary for the restoration of the permeability capacities of said membrane.

30. The method of claim 19 including utilizing the membrane potential difference as function of transmembrane pressure to determine the state of clogging of a membrane.

31. The method of claim 19 including utilizing the membrane potential difference as a function of transmembrane pressure to determine the frequency of cleaning of said membrane.

32. The method of claim 19 including utilizing the membrane potential difference as a function of transmembrane pressure for monitoring and evaluating the efficiency of cleaning of the membrane.

33. The method of claim 19 including utilizing the membrane potential difference as a function of transmembrane pressure for evaluating the efficiency of a membrane prior to being placed in service.

34. A device for determining the electrostatic charge state of a porous membrane, comprising: an electrical circuit for the measurement of the flow potential, said electrical circuit including a flow potential measuring device for measuring flow potential connected to a reading device for reading the measurements taken by the flow potential measuring device.

35. The device according to claim 34, wherein the flow potential measuring device includes Ag/AgCl electrodes.

36. The device according to claim 34, wherein said reading device includes a millivoltmeter having a high input impedance.

37. A method of monitoring the conditions of an immersed membrane filter used in wastewater treatment, comprising: placing a pair of electrodes across the membrane filter; operatively connecting the electrodes to a device for determining voltage; measuring the voltage differential across the membrane filter over a selected time period; measuring transmembrane pressure across the membrane over a selected time period; and utilizing the relationship of the voltage differential and transmembrane pressure over the selected time period to assess the condition or efficiency of the membrane filter.

38. The method of claim 37 including utilizing the measured voltage differential and the measured transmembrane pressure to determine the state of clogging of pores that form a part of the membrane filter.

39. The method of claim 37 wherein a relatively large value for differential voltage as a function of transmembrane pressure indicates a relatively clean membrane filter while a relatively low differential voltage as a function of transmembrane pressure indicates a relatively clogged membrane filter.

40. The device of claim 34 wherein the flow potential measuring device comprises a pair of electrodes with one electrode being disposed interiorly of the membrane and one electrode being disposed exteriorly of the membrane, and wherein the reading device comprises a millivoltmeter operatively connected to the electrodes for measuring differential voltage across the membrane.
